(19) United States
(12) Patent Application Publication
(10) Pub. No.: US 2026/0040826 A1
(43) Pub. Date: Feb. 5, 2026

(54) THREE-DIMENSIONAL TEXTURED CERAMIC PIEZOELECTRIC TRANSDUCERS AND METHODS OF FORMING SAME

(71) Applicant: L3Harris Technologies, Inc., Melbourne, FL (US)

(72) Inventors: Jonathan MILLER, Sandy, UT (US); Lindsay FUOCO, Murray, UT (US)

(21) Appl. No.: 18/790,304

(22) Filed: Jul. 31, 2024

(51) Int. Cl. H10N 30/50; H04R 17/00; H10N 30/05; H10N 30/084

(52) U.S. Cl. CPC H10N 30/501; H04R 17/00; H10N 30/05; H10N 30/084; H04R 2217/01

(57) ABSTRACT

A hollow three-dimensional piezoelectric device of conformable tape-casted textured ceramic material is formed sheets that are pre-cut in preselected patterns and smoothly conformably stacked in layers on a mold defining the desired three-dimensional shape. The final stack is isostatically compressed into the shape of the mold. The predetermined cut patterns are selectively configured to facilitate the smoothly conformable placement and stacking of the layers over the entire mold surface. The cut pattern may be three, four, or more convex circular triangles extending radially from a common point and that fit together to form a hemisphere when conformed to the mold. Each layer may comprise one or a plurality of tape-casted sheets, and the cut patterns in successive layers may be gradually dimensionally increased to accommodate the layer-to-layer increase in the diameter (i.e., thickness) of the stack.

### TECHNICAL FIELD

The present disclosure pertains generally to improvements in forming three-dimensional piezoelectric transducers from textured ceramic material and, more particularly, to forming hemispherical and other curved three-dimensional objects from such material.

### BACKGROUND

Textured piezoelectric ceramics technology is well known in the prior art; see, for example, US20140295138 (Yan et al), US10224476 (Yan et al) and US9773967 (Maurya et al), the entire disclosures in which are incorporated by reference herein. While textured ceramics have shown considerably improved piezoelectric performance compared to traditional polycrystalline lead-zirconate-titanate (PZT), there is currently no practical method to produce bowl-shaped hemispheres or other curved three-dimensional structures that fully benefit from textured ceramic technology. Such structures are used, for example as acoustic transducers such as hydrophones, acoustic projectors, microphones, speakers, etc. However, improved piezoelectric performance provided by textured ceramics is fully achieved only orthogonally of the planes of the aligned crystallites (i.e., grains) in the textured material. The conventional method of forming a curved three-dimensional textured ceramic body, such as a hollow or cup-like hemisphere, is to form a block of the polycrystalline ceramic material by stacking and pressing together multiple thin tape-casted sheets of the textured material, and then grinding or cutting the block into the desired shape. If the desired shape is a hollow hemisphere, for example, optimal omnidirectional piezoelectric performance would be achieved if the crystallites (grains) are aligned radially from the hemispheric center. However, the block formed from planar sheets is textured only in one direction, making it impossible to achieve omnidirectional or radial texturing by cutting the block.

The foregoing problem is illustrated diagrammatically in FIG. 1 in which a fanciful hemispheric piezoelectric acoustic transducer 10 is illustrated for explanatory purposes. In the left side of transducer 10, the textured grains 11 are linearly oriented as would be achieved if a multi-layer block of textured ceramic material is machined or otherwise cut as described above to define the hemispheric structure. Acoustic forces acting radially of hemispheric transducer 10 impact grains 11 at an angle to orthogonal, thereby lessening their piezoelectric effect. The right side of transducer 10 shows textured grains 12 having a radial orientation as required to enable radial forces to impact the grains orthogonally and thereby optimize piezoelectric effect and acoustic performance. Otherwise stated, since acoustic forces are optimally transduced radially, the linearly aligned textured grains have little or no added benefit; that is, the acoustic response is asymmetric and degraded in those regions. On the other hand, the radially aligned grains provide the benefits of texturing on all axes so that true, high omnidirectional performance would be achieved. This is also true for the reciprocal application (i.e. using the piezoelectric device as a projector). Specifically, when a voltage is applied between the inner and outer surfaces, the electric field in the piezoelectric material is radially directed (i.e., orthogonally of the textured grain) and maximum mechanical motion response is achieved.

It should be noted that there have been attempts to achieve radial texturing in curved three-dimensional piezoelectric devices using 3D printing. However, the texturing achieved by 3D printing has thus far been markedly poor compared the texturing achieved by pressing tape-casted sheets.

It is desirable, therefore, to maximize the advantages of ceramic texturing achieved via stacked and pressed tape-casted sheets in curved three-dimensional piezoelectric devices without sacrificing the piezoelectric performance benefits of texturing.

### SUMMARY

According to one aspect of the principles disclosed herein, in order to fabricate a curved three-dimensional piezoelectric device of desired shape, multiple conformable tape-casted textured ceramic sheets are pre-cut in preselected patterns and smoothly conformably stacked in layers on a mold defining the desired three-dimensional shape. The final stack may be compressed into the shape of the mold in a heated isopress. The predetermined cut patterns are selectively configured to facilitate the smoothly conformable placement and stacking of the layers over the entire mold surface to the desired thickness of the device. Where the desired three-dimensional device shape is a hollow hemisphere, the cut pattern may be three, four, or more convex circular triangles, (e.g., Reuleaux triangles) extending radially from a common point and that fit together to form a hemisphere when conformed to the hemispheric mold. Each layer may comprise one or a plurality of tape-casted sheets, and the cut patterns in successive layers may be gradually dimensionally increased to accommodate the layer-to-layer increase in the diameter (i.e., thickness) of the stack. The stack may be vacuum sealed in Mylar or other suitable material before placement in a heated isostatic press.

According to another aspect, a piezoelectric transducer having a predetermined curved three-dimensional configuration comprises a stack of multiple layers of sheets of conformable textured ceramic material cut into preselected patterns determined by the curved three-dimensional transducer configuration, the sheets being compressed together to form the transducer as a unitary hollow structure having the curved three-dimensional configuration and a predetermined thickness defined between inner and outer surfaces of the stack, wherein the sheets in the stack all have a common textured grain orientation that is maintained throughout the thickness of the hollow structure.

Another aspect of the principles described herein is a method of making a piezoelectric device in a hollow cup-like configuration from textured ceramic material comprising: cutting multiple tape-casted conformable sheets of textured ceramic material into preselected shaped patterns determined by the configuration of the piezoelectric device; conformably stacking the cut sheets in layers on a mold configured to shape the cut sheets into the hollow cup-like configuration, wherein the textured grains of the ceramic material are commonly oriented between opposite surfaces of the stack; and isostatically compressing said stack in said cup-like configuration.

### BRIEF DESCRIPTION OF THE DRAWINGS

By way of example, specific illustrative aspects of the present disclosure will now be described with reference to the accompanying drawings in which like reference numerals in the various figures represent similar or like components.

FIG. 1 is a diagrammatic elevation view in section of a fanciful hemispherical piezoelectric acoustic transducer created to illustrate the structural and functional differences between linear and radial grain alignment.

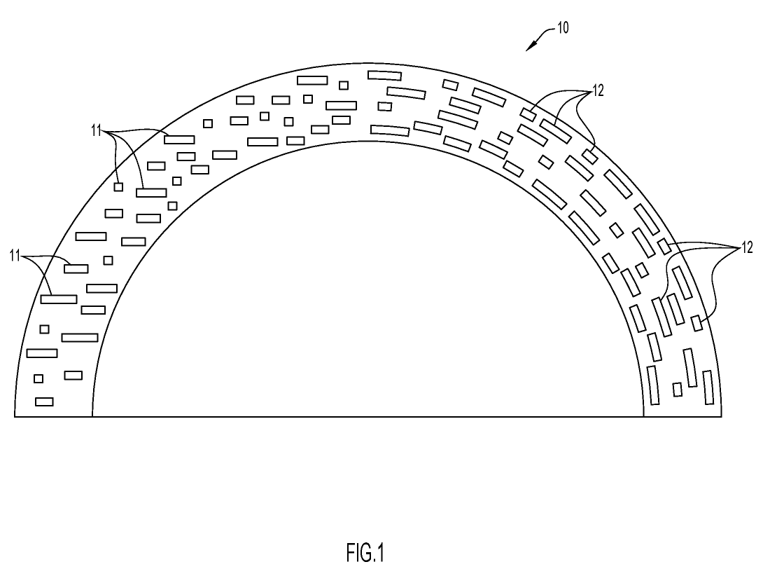

FIG. 2 is a plan view of a four-leaf cut pattern of a tape-casted textured ceramic sheet layer employed in forming a curved three-dimensional piezoelectric transducer according to the principles of the present disclosure.

FIG. 3 is a perspective view of the sheet layer of FIG. 2 deployed on a mold during the process of forming the transducer.

FIG. 4 is a plan view of a three-leaf cut pattern of a tape-casted textured ceramic sheet for use in forming a curved three-dimensional piezoelectric transducer according to the present disclosure.

FIG. 5 is a perspective view from above of a five-leaf cut pattern tape-casted textured ceramic sheet for use in forming a curved three-dimensional piezoelectric transducer according to the present disclosure, the patterned sheet shown being applied to a mold.

FIG. 6 is a diagrammatic elevation view in section of a hemispherical piezoelectric acoustic transducer fabricated according to the principles described herein.

### DETAILED DESCRIPTION

The presently disclosed devices and methods are described more fully hereinafter with reference to the accompanying drawings. It will be readily understood that the devices and methods as generally described herein and illustrated in the appended drawings may be arranged and designed in a wide variety of different configurations. Thus, the following more detailed description, as represented in the drawings, is not intended to limit the scope of the present disclosure but is merely representative of various devices and methods. While various aspects of the described principles are presented in the drawings, the drawings are not necessarily drawn to scale unless specifically indicated.

The techniques and approaches disclosed herein may be implemented in other specific forms without departing from their spirit or essential characteristics; that is, the described implementations are to be considered in all respects only as illustrative and not restrictive. The scope of inventions disclosed herein is therefore indicated by the appended claims rather than by this detailed description. All changes that come within the meaning and range of equivalency of the claims are to be embraced within their scope.

Reference throughout this specification to features, advantages, or similar language does not imply that all the features and advantages that may be realized with the disclosed devices and methods should be or are in any single implementation. Rather, language referring to the features and advantages is understood to mean that a specific feature, advantage, or characteristic described in connection with an implementation is included in at least one implementation. Thus, discussions of the features and advantages, and similar language, throughout this specification may, but do not necessarily, refer to the same implementation.

Furthermore, the described features, advantages, and characteristics of the disclosed principles may be combined in any suitable manner in one or more implementations. One skilled in the relevant art will recognize, considering the description herein, that the implementations can be practiced without one or more of the specific features or advantages of a particular implementation. In other instances, additional features and advantages may be recognized in certain implementations that may not be present in all implementations.

Reference throughout this specification to an "embodiment," "an aspect", or similar language means that a particular feature, structure, or characteristic described in connection with the indicated embodiment or aspect is included in at least that one embodiment or aspect, but not necessarily all embodiments or aspects.

Definitions: As used herein, the following terms are understood to have the indicated meanings: “Circular triangle” means a triangle with arcuate sides. “Radial”, “radially” and variations thereof refer to the radius extending to/from the center point of the hemispheric or other shaped device being referenced. “Reuleaux triangle” means an equilateral circular triangle where the three sides are centered with respect to their opposite vertices.

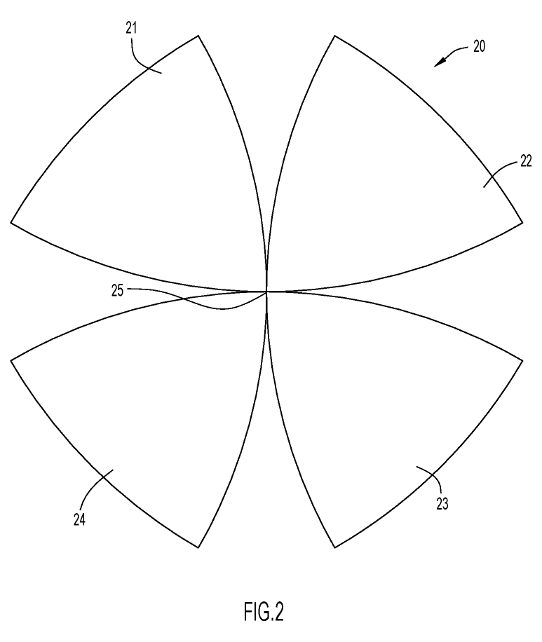

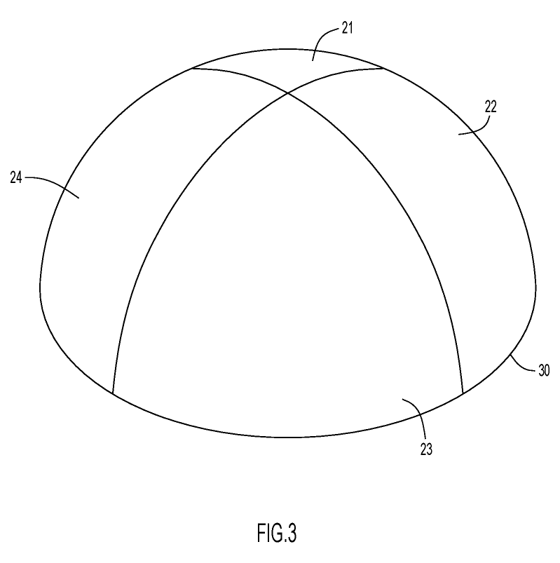

Referring to FIGS. 2 and 3 of the accompanying drawings, a four-leaf pattern layer 20 is cut from a thin tape-casted sheet of textured ceramic material, for example polycrystalline lead-zirconate-titanate (PZT). In the illustrated embodiment the cut pattern of layer 20 comprises four circular triangles 21, 22, 23, 24 with convex sides arranged in successive angular positions and extending from a common point 25 at which an apex of each triangle is located. A short proximal portion of two sides of each triangle extending from common point 25 is connected to a corresponding proximal side portion of an adjacent triangle. As best seen in FIG. 2, the four triangles may be congruent and equilateral, and may be Reuleaux triangles. Layer 20 may be a single sheet of the textured ceramic material or a plurality of sheets of the material in identically cut patterns. Cutting may be effected with a die, laser, or other tooling. The resulting layer is readily conformable to adapt to the contours of a mold such as that shown in FIG. 3. It will be appreciated that the triangles need not be congruent or equilateral; rather, they may have any regular or irregular configuration as long as they are conformable to cover the mold selected to form the final product shape.

The four-leaf pattern shown in FIG. 2 is preselected for its ability to form a hollow hemispherically-shaped piezoelectric acoustic transducer. Specifically, as shown in FIG. 3, multiple layers 20 may be stacked on and smoothly conform to a hemispheric-shaped mold 30 with common point 25 of the layers coincident with the apex of the mold. The layers are stacked in sufficient number as is necessary to achieve the desired thickness of the end product (e.g., a hemispheric bowl-shaped piezoelectric acoustic transducer). Successive layers 20 may be stacked with the leaves in successive layers angularly aligned, or successive layers may be angularly offset, for example with leaves in a successive layer overlying the abutting adjacent sides of leaves in a prior layer. Furthermore, the dimensions of the leaves in successively applied layers may be increased to accommodate the increasing thickness of the stack as layers are added. It will also be appreciated that layers of differently shaped cut patterns may be used in successive layers.

Once the stacking of layers on the form or mold is completed to the desired thickness, the stack is processed in a conventional manner for fabrication of polycrystalline PZT products, i.e., the stack is compressed (e.g., in a heated isostatic press), bisqued, heat treated, silvered and poled. The result is a hemispheric cup-like configuration of radially textured piezoelectric ceramic material capable of taking full advantage the improved piezoelectric properties afforded by textured ceramic material.

An important aspect of described process is cutting of conformable sheets of textured ceramic material into preselected patterns that can be smoothly conformed in a stack on a particular mold or form without creases or other deformities in the sheets. Simply stacking sheets or layers on a mold without cutting them into the pre-selected conformable patterns would result in such creases and deformities, resulting in misalignment of the textured grains. The preselected pattern to be cut will of course depend on the configuration of the mold which in turn, is defined by the curved three-dimensional shape of the final piezoelectric device being produced. Thus, the process herein described includes: cutting a sheet or plurality of sheets (using a die, laser or other cutting tool) into a predetermined pattern conformable to a mold or form; stacking layers of the patterned sheets, taking care to increase the dimensions of the pattern layer by layer as necessary to match the increasing inner to outer diameter thickness of the final stack; vacuum sealing the stacked layers in Mylar or other material suitable for heated isopressing; and compressing the mold-shaped shaped, for example in a heated isotatic press.

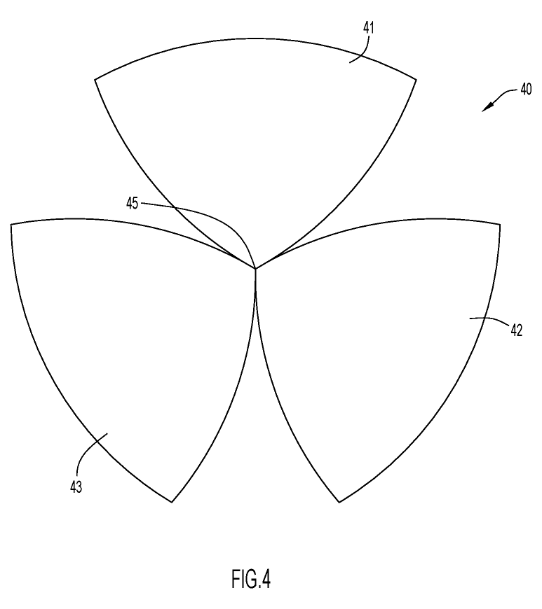

FIG. 4 illustrates a three-leaf pattern 40 cut from one or more conformable tape-casted sheets or layers of textured ceramic material. The cut pattern of layer 40 comprises four circular triangles 41, 42, 43 with convex sides arranged in successive angular positions and extending from a common point 45 at which an apex of each triangle is located. A short proximal portion of two sides of each triangle extending from common point 45 is connected to a corresponding proximal side portion of an adjacent triangle. The three triangles 41, 42, 43 may be congruent and equilateral, or they may be irregular incongruous triangles, depending on the shape of the mold. Layer 40 may be a single sheet of the textured ceramic material or a plurality of sheets of the material in identically cut patterns. The resulting layer is readily conformable to adapt to the contours of a mold such as that depicted in FIG. 3.

The three-leaf pattern 40 shown in FIG. 4 is preselected for its ability to form a hollow hemispherically-shaped piezoelectric acoustic transducer. Specifically, multiple layers 40 may be stacked on and smoothly conform to a hemispheric-shaped mold, such as mold 30, with common point 45 of the layers coincident with the apex of the mold. The layers are stacked in sufficient number as is necessary to achieve the desired thickness of the end product (e.g., a hemispheric bowl-shaped piezoelectric acoustic transducer). Successive layers 40 may be stacked with the leaves in successive layers angularly aligned, or successive layers may be angularly offset, for example with leaves in a successive layer overlying the abutting adjacent sides of leaves in a prior layer. Furthermore, the dimensions of the leaves in successively applied layers may be increased to accommodate the increasing thickness of the stack as layers are added. It will also be appreciated that layers of differently shaped cut patterns, for example the pattern of layer 20 of FIG. 2, may be alternated with layer 40 in successive layers applied to the mold.

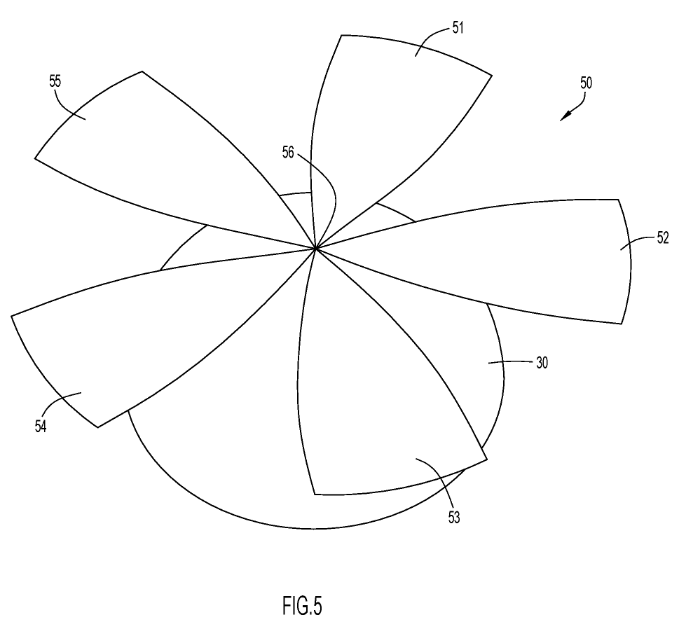

FIG. 5 illustrates a five-leaf pattern 50 being applied to mold 30. Pattern 50, like patterns 20 and 40, is cut from one or more conformable tape-casted sheets or layers of textured ceramic material. The cut pattern of layer 50 comprises five circular triangles 51, 52, 53, 54, 55 with convex sides arranged in successive angular positions and extending from a common point 56 at which an apex of each triangle is located. A short proximal portion of two sides of each triangle extending from common point 56 is connected to a corresponding proximal side portion of an adjacent triangle. The five triangles may be congruent and isosceles, or they may be irregular incongruous triangles, depending on the shape of the mold and the final piezoelectric product to be formed. Layer 50 may be a single sheet of the textured ceramic material or a plurality of sheets of the material in identically cut patterns. The resulting layer is readily conformable to adapt to the contours of mold 30.

The five-leaf pattern 50 is preselected for its ability to form a hollow hemispherically-shaped piezoelectric acoustic transducer. Specifically, multiple layers 50 may be stacked on and smoothly conform to a hemispheric-shaped mold, such as mold 30, with common point 56 of the layers coincident with the apex of the mold. The layers are stacked in sufficient number as is necessary to achieve the desired thickness of the end product (e.g., a hemispheric bowl-shaped piezoelectric acoustic transducer). Successive layers 50 may be stacked with the leaves in successive layers angularly aligned, or successive layers may be angularly offset, for example with leaves in a successive layer overlying the abutting adjacent sides of leaves in a prior layer. Furthermore, the dimensions of the leaves in successively applied layers may be increased to accommodate the increasing thickness of the stack as layers are added. It will also be appreciated that layers of differently shaped cut patterns, for example the pattern of layer 20 of FIG. 2, or the pattern of layer 40 of FIG. 4, may be alternated with layer 50 in successive layers applied to mold 30.

It will be understood that the regular hemispheric configuration of mold 30 is determined by the shape of the final product to be produced by that mold, and that other molds in the form of regular and regular ellipsoids or other three-dimensional shapes may be utilized to produce products appropriate thereto.

It will also be appreciated that the configurations of cut patterns in layers 20, 40 and 50 are only a few examples of patterns suitable to fabricate a hemispheric bowl-shaped acoustic transducer, and that other pattern configurations may be more appropriate to produce other curved hollow piezoelectric product shapes.

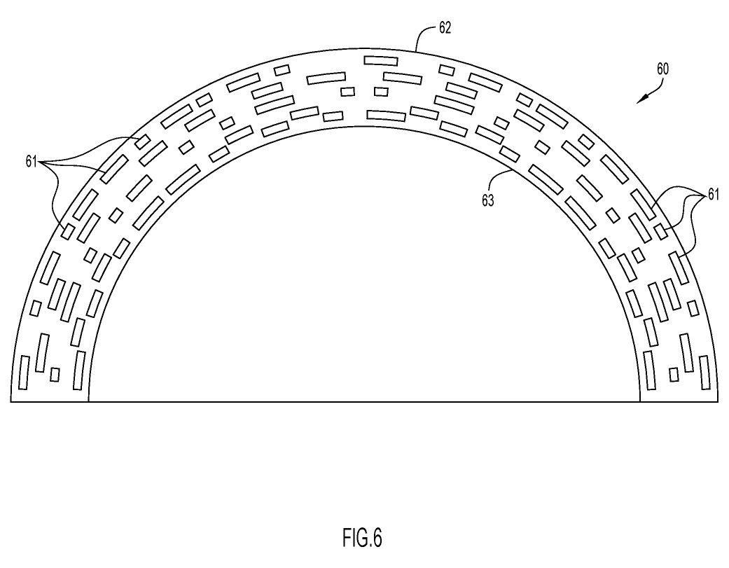

An example of an acoustic piezoelectric transducer 60 fabricated in accordance with the principles described herein is illustrated in FIG. 6. Transducer 60 has a bowl-shaped hemispherical configuration and is made from any one or more of the types of the above-described stacked layers of tape-casted textured ceramic sheets. The resulting structure has an outer surface 62 and an inner surface 63 defining the thickness of the transducer therebetween. As shown, all the textured grains 61 are radially oriented such that acoustic forces directed radially of the hemispheric transducer, orthogonally of inner surface 63 and outer surface 62, are also directed orthogonally of all the textured grains 61 to achieve maximum piezoelectric effect. This maximum effect is achieved whether transducer 60 is employed in an acoustic receiver such as a hydrophone or an acoustic projector such as a transmitter. This optimal orientation of the textured grains is achieved through the contouring of the stacked conformable tape-casted sheets on the desired mold.

In conclusion, provided for herein are techniques that provide for and facilitate fabrication of piezoelectric transducer having a predetermined curved three-dimensional configuration comprising a stack of multiple tape-casted sheets of textured ceramic material cut into predetermined conformable patterns determined by the aforesaid curved three-dimensional configuration, the sheets being compressed together to form transducer as a unitary three-dimensional structure having the curved three-dimensional configuration and a predetermined thickness, wherein said sheets in the stack all have a common grain orientation that is maintained throughout the thickness of the three-dimensional structure.

What is claimed is:

1. A piezoelectric transducer having a predetermined curved three-dimensional configuration comprising:
a stack of multiple layers of sheets of conformable textured ceramic material cut into preselected patterns determined by said curved three-dimensional configuration, said sheets being compressed together to form said transducer as a unitary hollow structure having said curved three-dimensional configuration and a predetermined thickness defined between inner and outer surfaces of the stack; and
wherein said sheets in said stack all have a common textured grain orientation that is maintained throughout the thickness of said hollow structure.

2. The transducer of claim 1, wherein said sheets are tape-casted sheets of said textured ceramic material.

3. The transducer of claim 2, wherein said three-dimensional configuration is a hollow hemisphere, and wherein said patterns comprise a plurality of circular triangles having convex sides.

4. The transducer of claim 3, wherein said triangles arranged in successive angular positions extending from a common point at which an apex of each triangle is located.

5. The transducer of claim 4, and wherein a proximal portion of each of two sides of each triangle extending from the common point is connected to a corresponding proximal side portion of an adjacent triangle.

6. The transducer of claim 5, wherein said plurality of triangles consists of four triangles.

7. The transducer of claim 5, wherein said plurality of triangles comprises at least three triangles.

8. The transducer of claim 3, wherein said circular triangles are Reuleaux triangles arranged in successive angular positions extending from a common point at which an apex of each triangle is located, and wherein a proximal portion of each of two sides of each triangle extending from the common point is connected to a corresponding proximal side portion of an adjacent triangle.

9. A method of making a piezoelectric device in a hollow cup-like configuration from textured ceramic material comprising;
cutting multiple tape-casted conformable sheets of textured ceramic material into preselected shaped patterns determined by the configuration of the piezoelectric device;
conformably stacking the cut sheets in layers on a mold configured to shape the cut sheets into the hollow cup-like configuration, wherein the textured grains are aligned radially from the hemispheric center; and isostatically compressing said stack in said cup-like configuration.

10. The method of claim 9, wherein cutting multiple tape-casted sheets comprises cutting the sheets into patterns comprising a plurality of circular triangles having convex sides.

11. The method of claim 10, wherein said patterns comprise a plurality of circular triangles having convex sides.

12. The method of claim 11, wherein said triangles are arranged in successive angular positions extending from a common point at which an apex of each triangle is located.

13. The method of claim 12, wherein a proximal portion of each of two sides of each triangle extending from the common point is connected to a corresponding proximal side portion of an adjacent triangle.

14. A method of fabricating a curved three-dimensional piezoelectric device of desired shape comprising:
providing multiple conformable tape-casted textured ceramic sheets pre-cut in preselected patterns and smoothly conformably stacked in layers on a mold defining the desired three-dimensional shape;
compressing the stack into the shape of the mold in a heated isopress;
wherein the preselected cut patterns are configured to facilitate smoothly conformable placement and stacking of the layers over the entire mold surface to the desired thickness of the device;
wherein the desired three-dimensional device shape is a hollow hemisphere, and the cut pattern comprises three or more convex circular triangles, extending radially from a common point and that fit together to form a hemisphere when conformed to the mold.

15. The method of claim 14, wherein each layer comprises one or a plurality of tape-casted sheets, and wherein the cut patterns in successive layers are gradually dimensionally increased to accommodate layer-to-layer increase in the thickness of the stack.
